(19) United States
(12) Patent Application Publication
(10) Pub. No.: US 2026/0125824 A1
(43) Pub. Date: May 7, 2026

(54) GALLIUM NITRIDE SINGLE CRYSTAL SUBSTRATE AND METHOD OF PRODUCING SAME

(71) Applicant: SUMITOMO CHEMICAL COMPANY, LIMITED, Tokyo (JP)

(72) Inventors: Takayuki SUZUKI, Ibaraki (JP); Takashi SATO, Ibaraki (JP); Toshio KITAMURA, Ibaraki (JP); Tetsuji FUJIMOTO, Ibaraki (JP)

(21) Appl. No.: 19/365,280

(22) Filed: Oct. 22, 2025

(30) Foreign Application Priority Data
Nov. 1, 2024 (JP) 2024-193238

(51) Int. Cl. C30B 29/40; C30B 25/20

(52) U.S. Cl. CPC C30B 29/406; C30B 25/20

(57) ABSTRACT

A gallium nitride single crystal substrate in which a low-index crystal plane closest to a principal surface of the substrate is a (0001) plane, wherein provided that thermal conductivity of the substrate along a thickness direction of the principal surface at 200° C. is R1(H), and thermal conductivity of the substrate along an in-plane direction at 200° C. is R2(H), R1(H) is 80 W/mK or higher and 120 W/mK or lower, and R2(H) is 80 W/mK or higher and 110 W/mK or lower.

### FIELD AND BACKGROUND OF THE INVENTION

The present disclosure relates to a gallium nitride single crystal substrate and a method of producing same.

Group III nitride semiconductors, typically represented by gallium nitride (GaN), are widely used as materials for semiconductor devices such as light-emitting devices and electronic devices. In order to improve the quality (e.g., semiconductor characteristics) of semiconductor devices constituted from group III nitride semiconductors, it has been desired to produce semiconductor stacks for manufacturing semiconductor devices or free-standing nitride semiconductor substrates so as to have satisfactory crystal quality.

A semiconductor device may be mounted on a heat sink in order to diffuse heat generated therein. From the viewpoint of enhancing heat transfer to the heat sink, high thermal conductivity is required for a GaN single crystal substrate that is used for the semiconductor device (see, for example, Japanese Patent Application Publication No. 2008-179536).

### RELATED APPLICATION

Patent Document 1: Japanese Patent Application Publication No. 2008-179536

### SUMMARY OF THE INVENTION

In an environment where a semiconductor device is actually used, the temperature may rise due to the operation of the device. On the other hand, the thermal conductivity of a GaN single crystal substrate has heretofore been measured under room temperature conditions, and measurement under high temperature conditions has not received much attention. Against this background, the present inventors have examined variations in the thermal conductivity of gallium nitride due to temperature, and confirmed that the thermal conductivity of gallium nitride tends to decrease as the temperature increases.

For this reason, it is required that a GaN single crystal substrate used for a semiconductor device be capable of maintaining high thermal conductivity so as to exhibit desired heat dissipation even when the temperature of the semiconductor device rises.

The present disclosure aims to provide a technique for maintaining high thermal conductivity under high-temperature environments in a gallium nitride single crystal substrate.

According to one aspect of the present disclosure, there is provided a gallium nitride single crystal substrate in which a low-index crystal plane closest to a principal surface of the substrate is a (0001) plane,
wherein, provided that thermal conductivity of the substrate along a thickness direction of the principal surface at 200° C. is R1(H), and thermal conductivity of the substrate along an in-plane direction at 200° C. is R2(H),
R1(H) is 80 W/mK or higher and 120 W/mK or lower, and R2(H) is 80 W/mK or higher and 110 W/mK or lower.

According to another aspect of the present disclosure, there is provided a method of producing a gallium nitride single crystal substrate, the method including:
(a) preparing a base substrate constituted from a gallium nitride single crystal in which a low-index crystal plane closest to a principal surface of the base substrate is a (0001) plane; and
(b) epitaxially growing a gallium nitride single crystal on the principal surface of the base substrate,
wherein in (b), under an ammonia-containing atmosphere with a growth pressure greater than 1 atm and 1.5 atm or lower, a source gas for forming the gallium nitride single crystal is supplied onto the base substrate, and concurrently ammonia is supplied from around a support member supporting the base substrate.

According to the present disclosure, high thermal conductivity can be maintained in a gallium nitride single crystal substrate even under high-temperature environments.

### BRIEF DESCRIPTION OF DRAWINGS

FIG. 1A is a schematic cross-sectional view illustrating a part of a method of producing a gallium nitride single crystal substrate according to one embodiment of the present disclosure;

FIG. 1B is a schematic cross-sectional view illustrating a part of a method of producing a gallium nitride single crystal substrate according to one embodiment of the present disclosure;

FIG. 1C is a schematic cross-sectional view illustrating a part of a method of producing a gallium nitride single crystal substrate according to one embodiment of the present disclosure;

FIG. 2 is a flowchart illustrating a method of producing a gallium nitride single crystal substrate according to the embodiment;

FIG. 3 is a schematic configuration diagram illustrating an example of an HVPE apparatus;

FIG. 4 is a diagram illustrating thermal conductivity R1 in a thickness direction at 25° C. and 200° C. in an example; and

FIG. 5 is a diagram illustrating thermal conductivity R2 in an in-plane direction at 25° C. and 200° C. in an example.

### DETAILED DESCRIPTION

### Findings Obtained by the Inventors

First, findings obtained by the present inventors will be described.

The present inventors have examined a method by which gallium nitride can maintain high thermal conductivity even at high temperatures.

In general, since a GaN crystal has crystal anisotropy, in a GaN single crystal substrate, thermal conductivity tends to differ between a thickness direction and an in-plane direction. Thermal conductivity in the in-plane direction is important from the viewpoint of diffusing heat generated inside the device and suppressing local overheating. Thermal conductivity in the thickness direction is important from the viewpoint of promoting the discharge of heat from the device to a heat sink.

The present inventors have confirmed temperature dependence of thermal conductivity in each direction, and found that in both directions, thermal conductivity tends to decrease as temperature increases, and that in particular, thermal conductivity in the thickness direction significantly decreases as temperature increases.

The present inventors further examined the decrease in thermal conductivity due to an increase in temperature, and found that the decrease is greatly influenced by point defects introduced into a GaN crystal. Various factors may cause the occurrence of point defects, one of which is desorption of nitrogen atoms during a crystal growth process. In the growth process of a GaN crystal, nitrogen atoms may desorb and be lost, thereby forming point defects. There is a correlation between the number of such point defects and the decrease in thermal conductivity due to an increase in temperature, and as the number of point defects increases, thermal conductivity tends to decrease more readily.

For this reason, the present inventors have examined a method for reducing point defects in a GaN crystal, in particular point defects formed by desorption of nitrogen atoms. As a result, from the viewpoint of suppressing desorption of nitrogen atoms, it has been found that in crystal growth of a GaN crystal, it is preferable to set the growth pressure to a pressurizing condition and to supply ammonia as a holder purge gas under an ammonia-containing atmosphere.

The term “holder purge” refers to supplying a predetermined gas around a holder, for example during crystal growth in an HVPE apparatus, for the purpose of removing crystals deposited on the holder for holding a base substrate or preventing a source gas from reaching the back side of the holder. In the holder purge, for example, a gas is supplied and flowed from a side opposite to a holding surface of the holder for the base substrate, that is, from the back side of the holder, toward a peripheral portion of the holder. This makes it feasible to locally bring the surroundings of the holder into a positive pressure state.

As a gas used for the holder purge, from the viewpoint of the above purposes, nitrogen gas, hydrogen gas, etc. is usually used. According to examinations by the present inventors, it has been found that, by supplying ammonia instead of nitrogen gas or the like, desorption of nitrogen atoms in a GaN crystal can be suppressed and point defects can be reduced.

The present disclosure is based on the above findings found by the inventors.

### Detailed Description of Embodiments of the Present Disclosure

Next, an embodiment of the present disclosure will be described below with reference to the drawings. It should be noted that the present disclosure is not limited to these examples, but is defined by the claims, and is intended to include all modifications within the meanings and scope that are equivalent to the claims.

### First Embodiment of the Present Disclosure

Hereinafter, a first embodiment of the present disclosure will be described with reference to the drawings.

### (1) Gallium Nitride Single Crystal Substrate

A gallium nitride single crystal substrate (hereinafter also simply referred to as a GaN substrate) according to this embodiment is configured as a disk-shaped substrate used in manufacturing a semiconductor stack or a semiconductor device. The GaN substrate is a free-standing substrate constituted from a gallium nitride (GaN) single crystal.

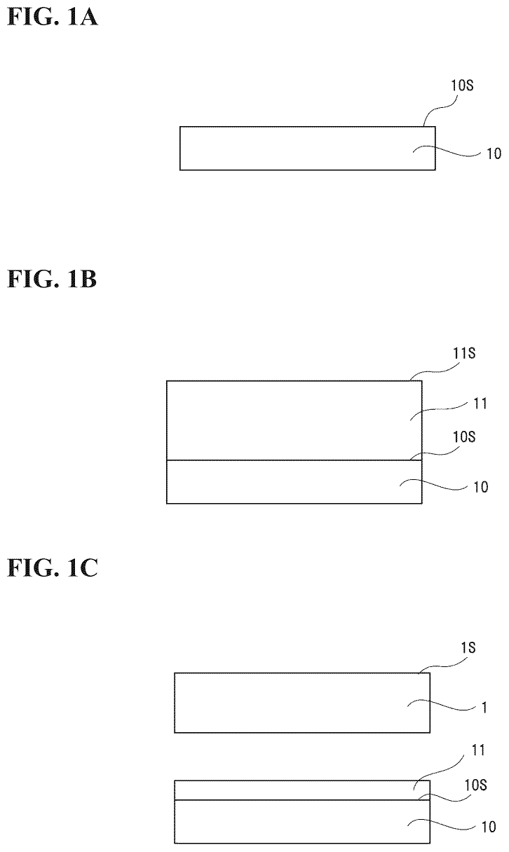

As illustrated in FIG. 1C, the GaN substrate 1 has a principal surface is serving as an epitaxial growth surface. The principal surface is of the GaN substrate 1 is a so-called epi-ready surface. A low-index crystal plane closest to the principal surface is of the GaN substrate 1 is, for example, a (0001) plane (+c-plane, Ga-polarity plane). Hereinafter, the (0001) plane is also referred to as the c-plane. The principal surface is of the GaN substrate 1 is, for example, mirror-finished, and the root mean square roughness (RMS) of the principal surface is of the GaN substrate 1 is preferably less than 1 nm.

Further, although the diameter of the GaN substrate 1 is not particularly limited, it is, for example, 50 mm or more. If the diameter of the GaN substrate 1 is less than 50 mm, productivity of semiconductor devices tends to be reduced. Therefore, it is preferable that the diameter of the GaN substrate 1 be 50 mm or more. The thickness of the GaN substrate 1 is, for example, 300 μm or more and 1 mm or less. If the thickness of the GaN substrate 1 is less than 300 m, the mechanical strength of the GaN substrate 1 may decrease, making it difficult to maintain a free-standing state. Therefore, it is preferable that the thickness of the GaN substrate 1 be 300 μm or more.

The GaN substrate 1 may contain an impurity in order to reduce resistivity. As the impurity, at least one from among silicon (Si) and germanium (Ge), which are n-type impurities, can be used, for example. Among these, Ge is preferable because it can be added at high concentrations. When the GaN substrate 1 contains an impurity, the impurity concentration is not particularly limited, but it is preferable that the impurity concentration (Ge concentration) be, for example, 1.0×10¹⁸ cm⁻³ or higher, more preferably 5.0×10¹⁸ cm⁻³ or higher, still more preferably 1.8×10¹⁹ cm⁻³ or higher, and even more preferably 1.0×10²⁰ cm⁻³ or higher. On the other hand, the upper limit of the impurity concentration is not particularly limited, but is preferably 1.0×10²¹ cm⁻³ or lower, and more preferably 5.0×10²⁰ cm⁻³ or lower. It should be noted that oxygen (O) may be unavoidably mixed into the GaN substrate 1 in addition to Si or Ge. O in the GaN substrate 1 has the effect of lowering resistivity similarly to Si and Ge, but conversely also acts to reduce thermal conductivity. Therefore, the concentration of O is preferably sufficiently low as to be negligible relative to the total concentration of Si and Ge in the GaN substrate 1, for example, preferably 1/10 or less, and more preferably 1/100 or less. Although the O concentration is not particularly limited, it is preferably, for example, 6×10¹⁶ cm⁻³ or lower.

The GaN substrate 1 of this embodiment is constituted with few point defects and configured to maintain high thermal conductivity even under high-temperature environments, by being formed under conditions that suppress desorption of nitrogen atoms, as will be described later. Specifically, when thermal conductivity along a thickness direction of the principal surface is of the GaN substrate 1 is denoted as R1 and thermal conductivity along an in-plane direction of the principal surface is is denoted as R2, R1(H) at 200° C. is 80 W/mK or higher and 120 W/mK or lower, and R2(H) at 200° C. is 80 W/mK or higher and 110 W/mK or lower. Therefore, the GaN substrate 1 readily discharges heat in the thickness direction and readily diffuses heat in the in-plane direction even under a high-temperature environment of 200° C.

The GaN substrate 1 is configured to have high thermal conductivity not only under high-temperature environments but also under room temperature environments. Specifically, it is preferable that thermal conductivity R1(L) in the thickness direction at 25° C. be, for example, 120 W/mK or higher. The upper limit is not particularly limited, but may be, for example, 230 W/mK or lower. On the other hand, it is preferable that thermal conductivity R2(L) in the in-plane direction at 25° C. be, for example, 150 W/mK or higher. The upper limit thereof is not particularly limited, but may be, for example, 250 W/mK or lower.

Since desorption of nitrogen atoms and resulting generation of point defects are suppressed in the GaN substrate 1, reduction of thermal conductivity due to temperature increase is suppressed. That is, the thermal conductivity R1 in the thickness direction of the GaN substrate 1 has a small rate of change when the temperature is raised from low temperature to high temperature. Specifically, it is preferable that the GaN substrate 1 have a small rate of change of thermal conductivity R1 in the thickness direction when the temperature is raised from 25° C. to 200° C., and that the rate of change x be 0.5 or less. Here, the rate of change x of thermal conductivity R1 in the thickness direction with temperature increase is expressed by x=(R1(L)−R1(H))/R1(L) using R1(L) at 25° C. and R1(H) at 200° C., and it is preferable that x satisfy x≤0.5. The lower the x, the smaller the decrease in thermal conductivity due to temperature increase, indicating that high thermal conductivity can be maintained even at high temperatures.

The thermal conductivity R2 in the in-plane direction of the GaN substrate 1 preferably has, similarly to the thermal conductivity R1 in the thickness direction, a small rate of change when the temperature is raised from 25° C. to 200° C., and the rate of change y is preferably 0.6 or less. Here, the rate of change y of the thermal conductivity R2 in the in-plane direction with temperature increase is expressed by y=(R2(L)−R2(H))/R2(L) using R2(L) at 25° C. and R2(H) at 200° C., and it is preferable that y satisfy y≤0.6. The lower the y, the smaller the decrease in thermal conductivity due to temperature increase, indicating that high thermal conductivity can be maintained even at high temperatures.

The GaN substrate 1 has both high thermal conductivity R1(H) in the thickness direction and high thermal conductivity R2(H) in the in-plane direction under a high-temperature environment (200° C.). Therefore, the GaN substrate 1 is configured so that variations in thermal conductivity between the thickness direction and the in-plane direction are small. That is, it is configured so that anisotropy of thermal conductivity is small under high-temperature environments. Specifically, R2(H)/R1(H), which represents variations in thermal conductivity, is 0.9 or more and 1.0 or less.

Similarly to under high-temperature environments, it is also desirable that the GaN substrate 1 have a small difference between the thermal conductivity R1 in the thickness direction and the thermal conductivity R2 in the in-plane direction at all operating temperatures of semiconductor devices. Since a GaN crystal has different lattice constants in the thickness direction and in the in-plane direction, the rate of change of thermal conductivity with temperature also has anisotropy. However, since the GaN substrate 1 of this embodiment has a small rate of change, R2/R1 falls within the range of 0.9 or more and 1.3 or less at any temperature from room temperature (25° C.) to high temperature (200° C.). At room temperature (25° C.), R2(L)/R1(L), which represents variations in thermal conductivity, is 1.1 or more and 1.3 or less. With such a GaN substrate 1, anisotropy of thermal conductivity is reduced regardless of environmental temperature, so that freedom of design in manufacturing semiconductor devices can be enhanced.

### (2) Method of Manufacturing Gallium Nitride Single Crystal Substrate

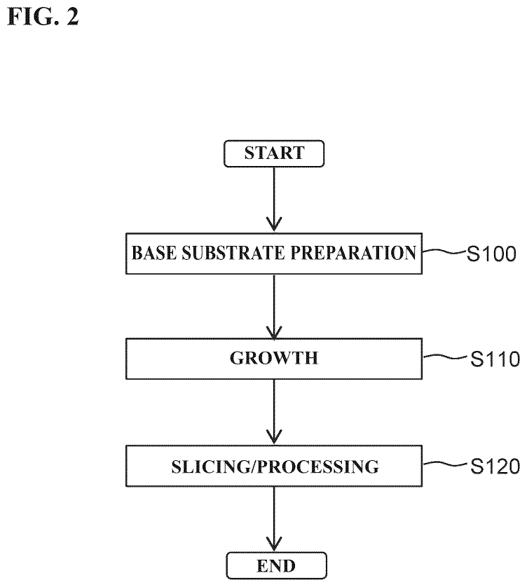

Next, a method of manufacturing the gallium nitride single crystal substrate described above will be explained with reference to FIGS. 1A to 1C and FIG. 2. FIGS. 1A to 1C illustrate schematic cross-sectional views showing part of a method of manufacturing a gallium nitride single crystal substrate according to an embodiment of the present disclosure. FIG. 2 illustrates a flowchart indicating the method of manufacturing a gallium nitride single crystal substrate according to this embodiment. As illustrated in FIG. 2, the method of manufacturing a gallium nitride single crystal substrate according to this embodiment includes, for example, a base substrate preparation step S100, a growth step S110, and a slicing/processing step S120.

### (S100: Base Substrate Preparation Step)

First, in the base substrate preparation step S100, as illustrated in FIG. 1A, a base substrate 10 constituted from a gallium nitride single crystal in which a low-index crystal plane closest to a principal surface 10s is a (0001) plane (c-plane) is prepared. Specifically, a commercially available gallium nitride single crystal substrate (not a template, but a free-standing substrate) may be used as the base substrate 10, or a base substrate 10 constituted from a gallium nitride single crystal may be prepared by a conventionally known void-assisted separation (VAS) method. The base substrate 10 may contain, for example, an n-type dopant such as Ge or Si, or may be non-doped. Preferably, the base substrate 10 is constituted by adding the same dopant according to the type of dopant to be added to a growth layer 11 described later. In this way, a concentration difference of dopant between the base substrate 10 and the growth layer 11 can be reduced.

### (S110: Growth Step)

Next, in the growth step S110, as illustrated in FIG. 1B, a GaN single crystal is epitaxially grown on the principal surface 10s of the base substrate 10 prepared in the base substrate preparation step S100, for example, with a c-plane as a growth surface. Specifically, for example, by supplying a source gas to the heated base substrate 10 by an HVPE method, epitaxial growth is directly performed on the principal surface 10s of the base substrate 10, and a growth layer 11 is grown.

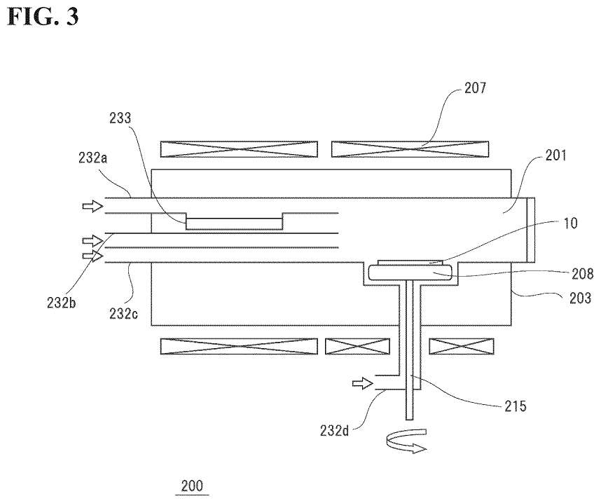

Here, the HVPE apparatus used in this embodiment will be described specifically with reference to FIG. 3.

FIG. 3 illustrates a schematic configuration diagram exemplifying the HVPE apparatus.

An HVPE apparatus 200 is constituted from a heat-resistant material such as quartz, and includes a hermetic container 203 in which a film formation chamber 201 is formed inside. In the film formation chamber 201, a support member 208 (hereinafter also referred to as a holder 208) for holding the base substrate 10 is provided. Around the outer periphery of the hermetic container 203, a heater 207 is provided for heating the base substrate 10 held on the holder 208 and the inside of the gas generator 233 to a desired temperature. The holder 208 is connected to a rotary shaft 215 having a rotation mechanism (not illustrated) and is configured to be rotatable. At one end of the hermetic container 203, gas supply pipes 232a to 232c are connected. These gas supply pipes 232a to 232c are each formed from a heat-resistant material such as quartz and are arranged to supply a predetermined gas to the base substrate 10 in the film formation chamber 201. At the other end of the hermetic container 203, an exhaust pipe (not illustrated) for exhausting the film formation chamber 201 is provided. In this embodiment, a gas supply pipe 232d is arranged to supply gas around the holder 208.

A chlorine-containing gas including a chlorine-based gas (for example, HCl or Cl₂) and a carrier gas is supplied to the gas supply pipe 232a. Downstream of the gas supply pipe 232a, a gas generator 233 for accommodating Ga melt as a source material is provided. In the gas generator 233, gallium chloride (GaCl) gas is generated by a reaction of the chlorine-containing gas with the Ga melt. The generated gallium chloride gas is supplied onto the base substrate 10. The gas supply pipe 232a for supplying GaCl gas as a Ga source gas preferably has its supply port positioned farther from the holder 208 than supply pipes 232b and 232c for supplying other source gases. According to such a configuration, unintended reactions between the GaCl gas discharged from the supply port and ammonia gas supplied by holder purge can be suppressed. As a result, desorption of nitrogen atoms by the holder purge can be suppressed more reliably.

A carrier gas together with a doping source-containing gas including a doping source gas is supplied to the gas supply pipe 232b. This doping source gas will be supplied onto the base substrate 10.

A carrier gas together with an NH₃-containing gas including ammonia gas (NH₃ gas) is supplied to the gas supply pipe 232c. This NH₃-containing gas will be supplied onto the base substrate 10 from the gas supply pipe 232c.

In this embodiment, the gas supply pipe 232d is arranged so as to supply a predetermined gas around the holder 208. In this embodiment, from the viewpoint of suppressing desorption of nitrogen atoms during the process of forming the growth layer 11, ammonia gas is supplied. The ammonia gas is supplied from the gas supply pipe 232d toward the back side of the holder 208 and is flowed from the back side of the holder 208 toward the surface side where the base substrate 10 is held. Therefore, ammonia gas can be continuously supplied to the periphery (outer edge) of the base substrate 10 and the growth interface of the growth layer 11 during crystal growth of the growth layer 11. Thereby, the periphery of the holder 208 can be locally brought into a positive pressure state with ammonia gas. As a result, the growth environment of the GaN crystal can be made N-rich, and even if nitrogen atoms are desorbed, they can be replenished.

Each component of the HVPE apparatus 200 is connected to a controller (not illustrated) configured as a computer, and is configured so that processing procedures and processing conditions described later are controlled by a program executed on the controller.

Specifically, in the growth step S110, the base substrate 10 to be processed is held on the holder 208 in the HVPE apparatus 200. While heating and evacuation of the inside of the film formation chamber 201 are carried out, NH₃ gas is supplied into the film formation chamber 201. For example, NH₃ gas is supplied into the film formation chamber 201 from the gas supply pipe 232c and/or the gas supply pipe 232d. When the inside of the film formation chamber 201 reaches a desired film formation temperature and film formation pressure, and the atmosphere in the film formation chamber 201 becomes an ammonia-containing atmosphere, gas is supplied from the gas supply pipes 232a to 232c, and GaCl gas as a source gas, doping source-containing gas, and NH₃ gas are supplied onto the base substrate 10. By reacting these gases, the growth layer can be formed onto the base substrate 10. The ammonia-containing atmosphere may include a gas other than ammonia, for example, hydrogen.

In this embodiment, from the viewpoint of suppressing desorption of nitrogen atoms from the GaN crystal and occurrence of point defects caused thereby, the crystal growth of the growth layer 11 is performed in such a condition that the inside of the film formation chamber 201 is an ammonia-containing atmosphere and in a pressurizing condition. Here, establishing a pressurizing condition for the growth pressure to as a growth condition in the growth step S110 means performing crystal growth at a pressure higher than atmospheric pressure. Specifically, the growth pressure is set to greater than 1 atm and 1.5 atm or lower. With such growth conditions, desorption of nitrogen atoms during crystal growth can be suppressed. Moreover, ammonia gas is supplied around the base substrate 10, and ammonia is always supplied to the periphery of the growth interface during the process of crystal growth. Thereby, desorption of nitrogen atoms can be suppressed more reliably.

Further, although oxygen (O) may generally be incorporated into the GaN crystal during its growth process, in this embodiment, such incorporation can be suppressed. Specifically, O tends to enter a nitrogen site as an n-type dopant, which may deteriorate the thermal conductivity under a room temperature environment or the decrease of thermal conductivity with temperature increase. In this embodiment, by performing crystal growth of GaN in a pressurizing condition with an ammonia-containing atmosphere while carrying out a holder purge with ammonia gas, the nitrogen partial pressure of the growth interface can be increased, and it is presumed that the entry of O into nitrogen sites can be suppressed as a result. Consequently, the O concentration in the GaN crystal can be reduced, and the O concentration can be made so low as to be negligible relative to the impurity concentration.

Among the growth conditions, other conditions besides the growth pressure are, for example, as follows.

As the growth temperature, the growth temperature is preferably 980° C. or higher and 1200° C. or lower.

The ratio of the supply rate of NH₃ gas as a group-V source gas to the supply rate of GaCl gas as a group-III source gas (hereinafter also referred to as a “V/III ratio”) is preferably 0.1 or more and 5.0 or less.

The partial pressure of GaCl gas is preferably 330 Pa or higher and 1300 Pa or lower.

### (S120: Slicing/Processing Step)

In a slicing/processing step S120, as illustrated in FIG. 1C, the growth layer 11 is sliced by a wire saw or the like along a cutting plane approximately parallel to the principal surface 11s (c-plane) of the growth layer 11, for example. Thus, at least one GaN substrate 1 having a diameter of 50 mm or more can be obtained as an as-sliced substrate. At this time, it is preferable to slice it so that the thickness of the GaN substrate 1 becomes, for example, 300 μm or more and 800 μm or less.

After obtaining the GaN substrate 1 as an as-sliced substrate, both surfaces of the GaN substrate 1 may be polished, for example, by a polishing apparatus.

In this embodiment, the GaN substrate 1 obtained in the slicing/processing step S120 may be used as a new base substrate 10, and the growth step S110 and the slicing/processing step S120 may be repeated a plurality of times (for example, four times or more).

By the above steps, the GaN substrate 1 according to this embodiment is manufactured.

The obtained GaN substrate 1 may, for example, be used to fabricate a semiconductor stack by epitaxially growing a semiconductor functional layer constituted from a group-III nitride semiconductor onto its principal surface is. After fabricating the semiconductor stack, electrodes and the like are further formed on the semiconductor stack, and the semiconductor stack is diced to cut out chips of a predetermined size. Thus, a semiconductor device may be fabricated. Since the GaN substrate 1 has high thermal conductivity and excellent heat dissipation, the device performance of the semiconductor device can be maintained at a high level for a long period of time.

### (4) Effects Obtained by this Embodiment

According to this embodiment, one or more of the following effects can be obtained.
(a) According to the GaN substrate 1 of this embodiment, the GaN crystal is grown and formed by performing a holder purge by locally supplying ammonia gas around the base substrate 10 while setting a pressurizing condition in an ammonia-containing atmosphere. By setting the pressurizing condition in the ammonia-containing atmosphere, desorption of nitrogen atoms during the growth process of the GaN crystal can be suppressed. In addition, by performing the holder purge with ammonia gas, ammonia gas can be continuously supplied around the growth interface of the GaN crystal, and desorption of nitrogen atoms can be suppressed. As a result, desorption of nitrogen atoms during the growth process of the GaN crystal can be suppressed, and occurrence of point defects associated with desorption can be reduced. Consequently, in the GaN substrate 1, both the thermal conductivity R1 in the thickness direction and the thermal conductivity R2 in the in-plane direction can be maintained high even under a high-temperature environment. Specifically, the GaN substrate 1 is configured so that the thermal conductivity R1(H) in the thickness direction at 200° C. is 80 W/mK to 120 W/mK, and the thermal conductivity R2(H) in the in-plane direction at 200° C. is 80 W/mK to 110 W/mK. Accordingly, when a semiconductor device is fabricated using such a GaN substrate 1, high heat dissipation can be realized, and high device performance can be maintained.

As a comparative embodiment, when the ammonia-containing atmosphere is set in a depressurized condition, or when a holder purge is performed with hydrogen or nitrogen, desorption of nitrogen atoms during the growth process of the GaN crystal cannot be sufficiently suppressed, and point defects tend to increase. With a GaN substrate obtained under such conditions, even if high thermal conductivity is exhibited under a room temperature environment, the thermal conductivity tends to decrease under a high-temperature environment, and in particular, the thermal conductivity R1 in the thickness direction tends to decrease remarkably. In this respect, according to the growth conditions of this embodiment, decrease of thermal conductivity with temperature increase can be suppressed, and high thermal conductivity can be maintained even under a high-temperature environment.
(b) The GaN substrate 1 preferably has a thermal conductivity R1(L) in the thickness direction at 25° C. of 120 W/mK or more, and a rate of change x of R1 when the temperature is raised from 25° C. to 200° C. of 0.5 or less. Accordingly, in the GaN substrate 1, the thermal conductivity R1 in the thickness direction is high under a room temperature environment, and decrease of thermal conductivity with temperature increase is suppressed, and the thermal conductivity R1 in the thickness direction can be maintained high even under a high-temperature environment. Therefore, in a semiconductor device fabricated from the GaN substrate 1, even if the temperature rises, discharge of heat to a heat sink can be maintained.
(c) The GaN substrate 1 preferably has a thermal conductivity R2(L) along the in-plane direction at 25° C. of 150 W/mK or more, and a rate of change y of R2 when the temperature is raised from 25° C. to 200° C. of 0.6 or less. Accordingly, the GaN substrate 1 has high thermal conductivity R2 in the in-plane direction under a room temperature environment, and decrease of thermal conductivity with temperature increase is suppressed, and the thermal conductivity R2 in the in-plane direction can be maintained high even under a high-temperature environment. Therefore, in a semiconductor device fabricated from the GaN substrate 1, heat generated inside the device can be diffused, and local overheating can be more reliably suppressed.
(d) The GaN substrate 1 preferably has a thermal conductivity R1(L) along the thickness direction of the principal surface at 25° C. of 120 W/mK or more and 230 W/mK or less, and a thermal conductivity R2(L) along the in-plane direction at 25° C. of 150 W/mK or more and 250 W/mK or less. That is, the GaN substrate 1 can maintain high thermal conductivity in both the thickness direction and the in-plane direction even under a low-temperature environment. Accordingly, in a device fabricated from the GaN substrate 1, high heat dissipation can be realized.
(e) The GaN substrate 1 is preferably configured such that variations in thermal conductivity between the thickness direction and the in-plane direction are suppressed regardless of environmental temperature. Specifically, for the GaN substrate 1, it is preferable that, at any temperature in the range of 25° C. to 200° C., the thermal conductivity R1 in the thickness direction and the thermal conductivity R2 in the in-plane direction at the same temperature satisfy 1.3≥R2/R1≥0.9. Further, it is more preferable that R2(H)/R1(H) at 200° C. be 0.9 or more and 1.0 or less, and R2(L)/R1(L) at 25° C. be 1.1 or more and 1.3 or less. According to such a GaN substrate 1, freedom of design in semiconductor device fabrication can be improved.
(f) In this embodiment, the growth pressure in the growth atmosphere may be in any pressurizing condition, and preferably is greater than 1 atm and 1.5 atm or lower. By setting such a growth pressure, desorption of nitrogen atoms during the growth process of the GaN crystal can be more reliably suppressed.
(g) Further, in the growth process of the GaN crystal, it is preferable that the supply port of the gas supply pipe 232a for supplying Ga source gas be positioned farthest from the base substrate 10. Thereby, a reaction between the Ga source gas and ammonia gas supplied by a holder purge can be suppressed, and desorption of nitrogen atoms can be more reliably suppressed.

### Other Embodiments

Embodiments of the present disclosure have been described specifically above. However, the present disclosure is not limited to the above embodiments, and various modifications can be made without departing from the gist thereof.

In the above embodiments, a case has been described in which a GaN crystal is grown on a base substrate constituted from a GaN crystal. However, the present disclosure is not limited thereto. In the present disclosure, it is not limited to homoepitaxial growth, and heteroepitaxial growth may be performed. In this case, a conventionally known VAS method may be adopted, and after forming a growth layer by growing a GaN crystal on a base substrate, the growth layer may be removed.

In the above embodiments, the case has been described in which the growth layer 11 is sliced in the slicing/processing step S120 using a wire saw. However, for example, an outer blade slicer, an inner blade slicer, an electric discharge machine, or the like may be used.

### Examples

Next, examples according to the present disclosure will be described. These examples are merely examples of the present disclosure, and the present disclosure is not limited by these examples.

### (1) Fabrication of Gallium Nitride Single Crystal Substrate

Gallium nitride single crystal substrates of Samples 1 to 3 were fabricated as follows.

### [Fabrication Conditions of Sample 1](Base Substrate)

Material: GaN
Fabrication method: VAS method
Diameter: 2 inches
Thickness: 400 μm
Low-index crystal plane closest to principal surface: c-plane
Root mean square roughness RMS of principal surface: 0.5 nm

### (Growth Layer)

Material: GaN
Growth method: HVPE method
Growth temperature: 980° C. or higher and 1200° C. or lower
Growth pressure: 1.2 atm or higher and 1.5 atm or lower
Growth atmosphere: ammonia, hydrogen
V/III ratio: 0.1 or more and 5.0 or less
Ge doping method: GeCl₄ gas
Partial pressure of GeCl₄ gas: 0.15 Pa
Thickness of growth layer: 2000 μm (holder purge conditions)
Gas: ammonia gas
Supply amount: 1.0 L/min

### (Slicing/Processing Conditions)

Thickness of gallium nitride single crystal substrate: 400 μm
Kerf loss: 200 μm

A GaN substrate was fabricated under the above fabrication conditions. When the Ge concentration of the GaN substrate was measured by secondary ion mass spectrometry, the Ge concentration was 7.05×10¹⁸ cm⁻³. When the O concentration was measured similarly, the O concentration was 1.00×10¹⁶ cm⁻³ to 6.00×10¹⁶ cm⁻³. That is, the O concentration was 1/100 or less of the Ge concentration.

### [Fabrication Conditions of Sample 2]

In Sample 2, a GaN substrate was fabricated under similar conditions to Sample 1, except that the partial pressure of GeCl₄ gas was set to 0.39 Pa so that the Ge concentration was higher than that of Sample 1. When the Ge concentration of the GaN substrate was measured by secondary ion mass spectrometry, the Ge concentration was 1.99×10¹⁹ cm⁻³. When the O concentration was measured similarly, the O concentration was 1.00×10¹⁶ cm⁻³ to 6.00×10¹⁶ cm⁻³. That is, the O concentration was 1/100 or less of the Ge concentration.

### [Fabrication Conditions of Sample 3]

In Sample 3, a GaN substrate was fabricated under similar conditions to Sample 1, except that the partial pressure of GeCl₄ gas was set to 1.85 Pa so that the Ge concentration was higher than that of Sample 2. When the Ge concentration of the GaN substrate was measured by secondary ion mass spectrometry, the Ge concentration was 1.03×10²⁰ cm⁻³. When the O concentration was measured similarly, the O concentration was 1.00×10¹⁶ cm⁻³ to 6.00×10¹⁶ cm⁻³. That is, the O concentration was 1/100 or less of the Ge concentration.

### [Fabrication Conditions of Sample 4]

In Sample 4, a GaN substrate was fabricated under similar conditions to Sample 1, except that the partial pressure of GeCl₄ gas was set to 0.06 Pa so that the Ge concentration was lower than that of Sample 1. When the Ge concentration of the GaN substrate was measured by secondary ion mass spectrometry, the Ge concentration was 3.42×10¹⁸ cm⁻³. When the O concentration was measured similarly, the O concentration was 1.00×10¹⁶ cm⁻³ to 6.00×10¹⁶ cm⁻³. That is, the O concentration was 1/50 or less of the Ge concentration.

### [Fabrication Conditions of Sample 5]

In Sample 5, although the growth of the GaN crystal was performed in an ammonia-containing atmosphere, the growth pressure was set low at 0.6 atm. Further, the partial pressure of GeCl₄ gas was set to 0.39 Pa and the Ge concentration was adjusted to a level similar to that of Sample 2. Furthermore, during the growth of the GaN crystal, a holder purge was performed by supplying nitrogen gas instead of ammonia gas to the outer edge of the base substrate. Except for the above, a GaN substrate was fabricated under similar conditions to Sample 1. When the Ge concentration of the GaN substrate was measured by secondary ion mass spectrometry, the Ge concentration was 2.08×10¹⁹ cm⁻³. When the O concentration was measured similarly, the O concentration was higher than that of Samples 1 to 4, and was 6.00×10¹⁶ cm⁻³ to 1.00×10¹⁷ cm⁻³.

### (2) Evaluation

The thermal conductivity of the GaN substrates fabricated was measured in both the thickness direction and the in-plane direction at respective temperature conditions of 25° C. and 200° C.

The thermal conductivity R1(L) [W/m·K] in the thickness direction at 25° C. was calculated from R1(L)=αρCp by determining density ρ [kg/m³], specific heat Cp [J/kg·K], and thermal diffusivity α [m²/s] of a sample taken from the GaN substrate. Density was determined by the Archimedes method. Specific heat was determined by specific heat capacity measurement using a DSC method. Thermal diffusivity was determined by thermal diffusivity measurement using a flash method. The thermal diffusivity was measured using a measurement device “LFA467HT” manufactured by NETZSCH.

The thermal conductivity R1(H) [W/m·K] in the thickness direction at 200° C. was calculated by determining density, specific heat, and thermal diffusivity of a sample taken from the GaN substrate in a similar manner to that described above, with the sample temperature changed from 25° C. to 200° C. The density at 25° C. was adopted, since thermal expansion due to temperature increase is negligible.

The thermal conductivity R2(L) [W/m·K] in the in-plane direction at 25° C. was calculated from R2(L)=αρCp by determining density ρ [kg/m³], specific heat Cp [J/kg·K], and thermal diffusivity α [m²/s] of a sample taken from the GaN substrate. Thermal diffusivity was determined by thermal diffusivity measurement using an optical AC method. As the thermal diffusivity measurement device, “Laser PIT” manufactured by ULVAC-RIKO, Inc. was used. The density and specific heat were measured in a similar manner to the above.

The thermal conductivity R2(H) [W/m·K] in the in-plane direction at 200° C. was calculated by determining density, specific heat, and thermal diffusivity of a sample taken from the GaN substrate in a similar manner to that described above, with the sample temperature changed from 25° C. to 200° C. The density at 25° C. was adopted, since thermal expansion due to temperature increase is negligible.

### (3) Evaluation Results

The evaluation results are summarized in Table 1 below.

TABLE 1

| | | Sample 1 | Sample 2 | Sample 3 | Sample 4 | Sample 5 |
|---|---|---|---|---|---|---|
| Ge concentration (cm⁻³) | | 7.05E+18 | 1.99E+19 | 1.03E+20 | 3.4E+18 | 2.08E+19 |
| Thermal | R1(L) at 25° C. | 186 | 156 | 141 | 216 | 151 |
| conductivity R1 in | R1(H) at 200° C. | 107 | 103 | 91.6 | 113 | 74 |
| thickness direction | | | | | | |
| [W/m · K] | | | | | | |
| Rate of change x in thermal | | 0.42 | 0.34 | 0.35 | 0.48 | 0.51 |
| conductivity R1 | | | | | | |
| Thermal | R2(L) at 25° C. | 237 | 202 | 173 | 246 | 198 |
| conductivity R2 in | R2(H) at 200° C. | 96.5 | 95.6 | 89.1 | 109 | 78 |
| in-plane direction | | | | | | |
| [W/m · K] | | | | | | |
| Rate of change y in thermal | | 0.59 | 0.53 | 0.48 | 0.56 | 0.61 |
| conductivity R2 | | | | | | |
| Thermal | R2(L)/R1(L) | 1.27 | 1.29 | 1.23 | 1.14 | 1.31 |
| conductivity | R2(H)/R1(H) | 0.90 | 0.93 | 0.97 | 0.96 | 1.05 |
| variation | | | | | | |

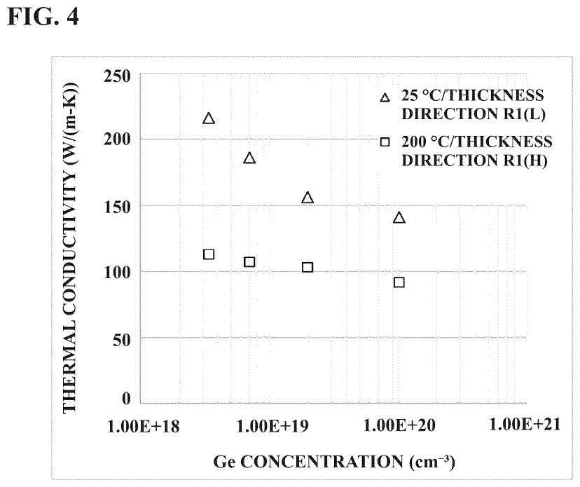

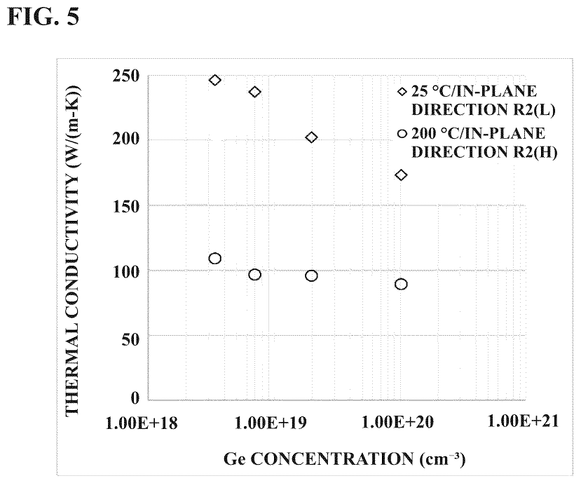

Further, variations in thermal conductivity R1 in the thickness direction depending on Ge concentration at 25° C. (R1(L)) and 200° C. (R1(H)) are illustrated in FIG. 4. Variations in thermal conductivity R2 in the in-plane direction depending on Ge concentration at 25° C. (R2(L)) and 200° C. (R2(H)) are illustrated in FIG. 5. In each figure, the horizontal axis indicates Ge concentration, and the vertical axis indicates thermal conductivity.

As illustrated in FIG. 4, it was confirmed that the thermal conductivity R1 in the thickness direction tends to decrease as the Ge concentration increases. As illustrated in FIG. 5, it was confirmed that the thermal conductivity R2 in the in-plane direction tends to decrease as the Ge concentration increases. It was also confirmed that the thermal conductivity in each direction tends to decrease as the temperature increases from 25° C. to 200° C.

It was confirmed that Samples 1 to 4 had high thermal conductivity in both the thickness direction and the in-plane direction, with R1(L) at 25° C. of 120 W/mK or more and R2(L) at 25° C. of 150 W/mK or more. Moreover, it was confirmed that the thermal conductivities R1(H) and R2(H) at 200° C. were both 80 W/mK or more, indicating high thermal conductivity even under a high-temperature environment.

It was also confirmed that Samples 1 to 4 each had a small decrease of thermal conductivity with temperature increase. Specifically, when the temperature was raised from 25° C. to 200° C., the rate of change x of the thermal conductivity R1 in the thickness direction was 0.5 or less, and the rate of change y of the thermal conductivity R2 in the in-plane direction was 0.6 or less.

The reason why high thermal conductivity was maintained not only under a room temperature environment but also under a high-temperature environment is presumed to be that the growth conditions adopted herein suppressed occurrence of point defects.

Moreover, in Samples 1 to 4, it was confirmed that variations between the thermal conductivity in the thickness direction and the thermal conductivity in the in-plane direction were small under both a room temperature environment (25° C.) and a high-temperature environment (200° C.), that is, anisotropy was small. It was also confirmed that, at any temperature in the range of 25° C. to 200° C., the thermal conductivity R1 in the thickness direction and the thermal conductivity R2 in the in-plane direction at the same temperature satisfied 1.3≥R2/R1≥0.9.

On the other hand, in Sample 5, although the thermal conductivities R1(L) and R2(L) at 25° C. were high, similar to those of Sample 1 and other samples, it was confirmed that the thermal conductivities R1(H) and R2(H) at 200° C. became significantly low. It was confirmed that the rates of change x and y of the thermal conductivity with temperature increase were both high, and the decrease of thermal conductivity with temperature increase was large. Furthermore, it was confirmed that variations in thermal conductivity were greater in Sample 5 than in Samples 1 to 4. These are presumed to be due to an increase in point defects caused by nitrogen desorption in the GaN crystal.

From the above, it was confirmed that by performing a holder purge with ammonia gas and setting a pressurizing condition in an ammonia-containing atmosphere during the growth of the growth layer, a GaN substrate could be fabricated which had high thermal conductivity under a room temperature environment and suppressed decrease of thermal conductivity with temperature increase. According to such a GaN substrate, since high heat dissipation can be exhibited even under a high-temperature environment, performance of a semiconductor device can be maintained at a high level for a long period of time.

### Preferred Embodiments of the Present Disclosure

Preferred embodiments of the present disclosure are described below supplementarily.

### Supplementary Description 1.

A gallium nitride single crystal substrate in which a low-index crystal plane closest to a principal surface of the substrate is a (0001) plane,
wherein provided that thermal conductivity of the substrate along a thickness direction of the principal surface at 200° C. is R1(H), and thermal conductivity of the substrate along an in-plane direction at 200° C. is R2(H),
R1(H) is 80 W/mK or higher and 120 W/mK or lower, and R2(H) is 80 W/mK or higher and 110 W/mK or lower.

### Supplementary Description 2.

The gallium nitride single crystal substrate according to supplementary description 1,
wherein provided that thermal conductivity of the substrate along the thickness direction of the principal surface at 25° C. is R1(L),

$$R 1 ( L ) is 120 W / mK or higher , and$$

$$R 1 ( H ) and R 1 ( L ) satisfy ( R 1 ( L ) - R 1 ( H ) ) / R 1 ( L ) \leq 0.5 .$$

### Supplementary Description 3.

The gallium nitride single crystal substrate according to supplementary description 1 or 2,
wherein provided that thermal conductivity of the substrate along the in-plane direction at 25° C. is R2(L),

$$R 2 ( L ) is 150 W / mK or higher , and$$

$$R 2 ( H ) and R 2 ( L ) satisfy ( R 2 ( L ) - R 2 ( H ) ) / R 2 ( L ) \leq 0.6 .$$

### Supplementary Description 4.

The gallium nitride single crystal substrate according to any one of supplementary descriptions 1 to 3,
wherein R1(H) and R2(H) satisfy 1≥R2(H)/R1(H)≥0.9.

### Supplementary Description 5.

The gallium nitride single crystal substrate according to supplementary description 1,
wherein provided that thermal conductivity of the substrate along the thickness direction of the principal surface at an arbitrary temperature within a range of 25° C. to 200° C. is R1, and thermal conductivity of the substrate along the in-plane direction at the same arbitrary temperature is R2,

$$R 1 and R 2 satisfy 1.3 \geq R 2 / R 1 \geq 0.9 .$$

### Supplementary Description 6.

The gallium nitride single crystal substrate according to supplementary description 1,
wherein provided that thermal conductivity of the substrate along the thickness direction of the principal surface at 25° C. is R1(L), and thermal conductivity of the substrate along the in-plane direction at 25° C. is R2(L),

$$R 1 ( L ) and R 2 ( L ) satisfy 1. 3 \geq R 2 ( L ) / R 1 ( L ) \geq 1.1 .$$

Supplementary description 7.

The gallium nitride single crystal substrate according to any one of supplementary descriptions 1 to 6,
wherein the substrate contains an impurity including germanium,
and the germanium concentration is 1.0×10¹⁸ cm⁻³ or higher.

### Supplementary Description 8.

A gallium nitride single crystal substrate in which a low-index crystal plane closest to a principal surface of the substrate is a (0001) plane,
wherein provided that thermal conductivity of the substrate along a thickness direction of the principal surface at 25° C. is R1(L), and thermal conductivity of the substrate along an in-plane direction at 25° C. is R2(L),
R1(L) is 120 W/mK or higher and 230 W/mK or lower, and R2(L) is 150 W/mK or higher and 250 W/mK or lower.

### Supplementary Description 9.

The gallium nitride single crystal substrate according to supplementary description 8, wherein R1(L) and R2(L) satisfy 1.3≥R2(L)/R1(L)≥1.1.

### Supplementary Description 10.

A method of producing a gallium nitride single crystal substrate, the method comprising:
(a) preparing a base substrate constituted from a gallium nitride single crystal in which a low-index crystal plane closest to a principal surface of the base substrate is a (0001) plane; and
(b) epitaxially growing a gallium nitride single crystal on the principal surface of the base substrate,
wherein in (b), under an ammonia-containing atmosphere with a growth pressure greater than 1 atm and 1.5 atm or lower, a source gas for forming the gallium nitride single crystal is supplied onto the base substrate, and concurrently ammonia is supplied from around a support member supporting the base substrate.

### Supplementary Description 11.

The method of producing a gallium nitride single crystal substrate according to supplementary description 10,
wherein in (b), among supply ports for supplying the source gas, a supply port for supplying a Ga-containing gas is arranged farther from the support member than supply ports for supplying other source gases.

### EXPLANATION OF REFERENCE SIGNS

1 Gallium nitride single crystal substrate (GaN substrate)
10 Base substrate
11 Growth layer

What is claimed is:

1. A gallium nitride single crystal substrate in which a low-index crystal plane closest to a principal surface of the substrate is a (0001) plane,
wherein provided that thermal conductivity of the substrate along a thickness direction of the principal surface at 200° C. is R1(H), and thermal conductivity of the substrate along an in-plane direction at 200° C. is R2(H),
R1(H) is 80 W/mK or higher and 120 W/mK or lower, and R2(H) is 80 W/mK or higher and 110 W/mK or lower.

2. The gallium nitride single crystal substrate according to claim 1,
wherein provided that thermal conductivity of the substrate along the thickness direction of the principal surface at 25° C. is R1(L),
$$R 1 ( L ) is 120 W / mK or higher , and$$
$$R 1 ( H ) and R 1 ( L ) satisfy ( R 1 ( L ) - R 1 ( H ) ) / R 1 ( L ) \leq 0.5 .$$

3. The gallium nitride single crystal substrate according to claim 1,
wherein provided that thermal conductivity of the substrate along the in-plane direction at 25° C. is R2(L),
$$R 2 ( L ) is 150 W / mK or higher , and$$
$$R 2 ( H ) and R 2 ( L ) satisfy ( R 2 ( L ) - R 2 ( H ) ) / R 2 ( L ) \leq 0.6 .$$

4. A method of producing a gallium nitride single crystal substrate, the method comprising:
(a) preparing a base substrate constituted from a gallium nitride single crystal in which a low-index crystal plane closest to a principal surface of the base substrate is a (0001) plane; and
(b) epitaxially growing a gallium nitride single crystal on the principal surface of the base substrate,
wherein in (b), under an ammonia-containing atmosphere with a growth pressure greater than 1 atm and 1.5 atm or lower, a source gas for forming the gallium nitride single crystal is supplied onto the base substrate, and concurrently ammonia is supplied from around a support member supporting the base substrate.
